(19) United States
(12) Patent Application Publication
(10) Pub. No.: US 2022/0051914 A1
(43) Pub. Date: Feb. 17, 2022

(54) Wafer Susceptor

(71) Applicant: ENKRIS SEMICONDUCTOR, INC., Suzhou (CN)

(72) Inventors: Kai LIU, Suzhou (CN); Kai CHENG, Suzhou (CN)

(21) Appl. No.: 17/513,111

(22) Filed: Oct. 28, 2021

Related U.S. Application Data
(63) Continuation of application No. PCT/CN2019/084966, filed on Apr. 29, 2019.

(51) Int. Cl. H01L 21/67; H01L 21/687

(52) U.S. Cl. CPC H01L 21/67103; H01L 21/68785

(57) ABSTRACT

A wafer susceptor includes a plurality of grooves and a convex structure disposed in one groove of the plurality of grooves. The convex structure is asymmetrical, and a convex part of the convex structure is far away from a circle center of a wafer susceptor. The surface temperature of a portion of a substrate far away from the circle center of the wafer susceptor is increased. That is, the temperature of the convex position is basically the same as that of other positions on the substrate, the surface of the entire substrate is heated more uniformly, and thus the wavelength of an epitaxial wafer formed on the substrate is also more uniform, and the quality of the epitaxial wafer is promoted.

### CROSS-REFERENCE TO RELATED APPLICATIONS

The present application is a continuation application of International Application No. PCT/CN2019/084966 filed on Apr. 29, 2019. The application is incorporated herein by reference in its entireties.

### TECHNICAL FIELD

The present application relates to the field of semiconductor preparation, in particular to a wafer susceptor.

### BACKGROUND

A general preparation process of an epitaxial wafer mainly includes: putting a substrate of the epitaxial wafer into a groove of a wafer susceptor, putting the substrate into a Metal-Organic Chemical Vapor Deposition (MOCVD) reaction chamber together with the wafer susceptor, growing other epitaxial layers on the substrate of the epitaxial wafer by setting temperature, and introducing gas and the like.

During the preparation process of the epitaxial wafer, the substrate of the epitaxial wafer is in direct contact with a bottom of the groove of the wafer susceptor, and a heating way of the substrate is contact heat conduction, resulting in uneven heating of the substrate.

### SUMMARY

During a preparation process of an epitaxial wafer, the epitaxial wafer may warp due to the preparation environment, preparation materials and other issues. Compared with a wafer susceptor, the more convex a portion of the substrate is, the lower temperature the portion of the substrate is subjected to, so that surface temperature of the entire substrate is not uniform, resulting in uneven wavelength of the epitaxial wafer on the substrate.

In view of this, an embodiment of the present application provides a wafer susceptor. The wafer susceptor includes: a plurality of grooves; and a convex structure disposed in one groove of the plurality of grooves. The convex structure is asymmetrical, and a convex part of the convex structure is far away from a circle center of a wafer susceptor.

Further, a cross-sectional shape of the convex structure includes one of arc, triangle, trapezoid and rectangle.

Further, a cross-sectional shape of the convex structure includes a combination of more of arc, triangle, trapezoid and rectangle.

Further, the convex structure includes a single-layer structure, or a multi-layer structure.

Further, a height of the convex structure is in a range of 50 μm-150 μm.

Another embodiment of the present application provides a wafer susceptor. The wafer susceptor further includes: a step structure disposed on an edge of the groove.

Further, there is a distance between the convex structure and the step structure in a horizontal direction.

Further, a height of the step structure is in a range of 100 μm-300 μm.

Further, a height of the convex structure is not greater than a height of the step structure of the groove.

Further, from the highest point of the convex part towards an edge of the groove, a height of the convex structure becomes smaller and smaller.

Further, the highest point of the convex part is disposed, with respect to a center of the groove, far away from the circle center of the wafer susceptor.

In the present application, when the wafer susceptor is in a reaction chamber, an airflow is blown outward from the circle center of the wafer susceptor, and thus other epitaxial layers are formed on the substrate. In the substrate, the farther away from the circle center of the wafer susceptor, the lower surface temperature, the higher the distribution of Metal Organic (MO) source deposited on the substrate, and the greater wavelength of the epitaxial wafer. Therefore, the asymmetrical convex structure is disposed at the bottom of the groove where the epitaxial substrate is placed, and a convex part of the convex structure deviates from the circle center of the wafer susceptor, so that the surface temperature of a portion of the substrate far away from the circle center of the wafer susceptor is higher, the surface temperature of the entire substrate is more uniform, and thus the wavelength of the epitaxial wafer formed on the substrate is also more uniform.

In order to make the above and other purposes, features, and advantages of the present application more obvious and understandable, preferred embodiments are described in detail in the following with reference to accompanying drawings.

### BRIEF DESCRIPTION OF DRAWINGS

In order to more clearly illustrate technical solutions in embodiments of the present application or the prior art, the accompanying drawings used in the embodiments will be briefly introduced below. Obviously, the accompanying drawings in the following description are only some embodiments of the present application, and for a person of ordinary skill in the art, other accompanying drawings may be obtained based on these accompanying drawings without paying creative efforts. The above and other purposes, features and advantages of the present application will be clearer through the accompanying drawings. The same reference numerals indicate the same parts throughout the accompanying drawings. The accompanying drawings are not deliberately drawn to scale according to the actual size, with an emphasis on illustrating the gist of the present application.

FIG. 1 is a top view structure diagram of a wafer susceptor according to an embodiment of the present application.

FIG. 2 is a cross-sectional structure diagram of one groove in a wafer susceptor according to an embodiment of the present application.

FIG. 3 is a cross-sectional structure diagram of one groove according to another embodiment of the present application.

FIG. 4 is a cross-sectional structure diagram of one groove according to another embodiment of the present application.

FIG. 5 is a cross-sectional structure diagram of one groove according to another embodiment of the present application.

FIG. 6 is a cross-sectional structure diagram of one groove according to another embodiment of the present application.

FIG. 7 is a cross-sectional structure diagram of one groove according to another embodiment of the present application.

FIG. 8 is a cross-sectional structure diagram of one groove according to another embodiment of the present application.

FIG. 9 is a top view of an asymmetrical convex structure in one groove according to an embodiment of the present application.

### DETAILED DESCRIPTION OF THE EMBODIMENTS

Technical solutions in embodiments of the present application are clearly and completely described in the following with reference to accompanying drawings in the embodiments of the present application. It is obvious that described embodiments are only a part of the embodiments of the present application, and not all embodiments. Based on the embodiments in the present application, all other embodiments obtained by those skilled in the art without creative efforts are within the protective scope of the present application.

It should be noted that similar reference numbers and letters indicate similar items in the following accompanying drawings. Therefore, once an item is defined in one drawing, the term does not need to be further defined and explained in subsequent accompanying drawings. Meanwhile, in descriptions of the present application, terms including “first”, “second”, “third”, etc. are only used for distinguishing description, and cannot be understood as indicating or implying relative importance. In descriptions of the embodiments of the present application, it should be understood that when one layer (or film), region, pattern or structure is referred to as being “on” or “under” another substrate, another layer (or film), another region, another pad, or another pattern, it may be “directly” or “indirectly” on another substrate, another layer (or film), another region, another pad, or another pattern, or there may also be one or more intermediate layers. The position of a layer has been described with reference to the accompanying drawings. For the purpose of convenience and clarity, the thickness and size of each layer shown in the accompanying drawings may be enlarged, omitted, or schematically drawn. In addition, the size of a component does not fully reflect the actual size.

During a preparation process of an epitaxial wafer, the epitaxial wafer may be warped due to the preparation environment, preparation materials and other problems. Compared with a wafer susceptor, the more convex a portion of the substrate is, the lower temperature the portion of the substrate is subjected to, so that surface temperature of the entire substrate is not uniform, resulting in uneven wavelength of the epitaxial wafer on the substrate, which affects the quality of the epitaxial wafer.

To solve the above problems, an embodiment of the present application provides a wafer susceptor. The wafer susceptor includes a plurality of grooves 2 and a convex structure 22 disposed in one groove of the plurality of grooves 2. The convex structure 22 is asymmetrical. A convex part of the convex structure 22 is far away from a circle center of a wafer susceptor 1.

Further, the wafer susceptor further includes a step structure 21. The step structure 21 is disposed on an edge of the groove 2.

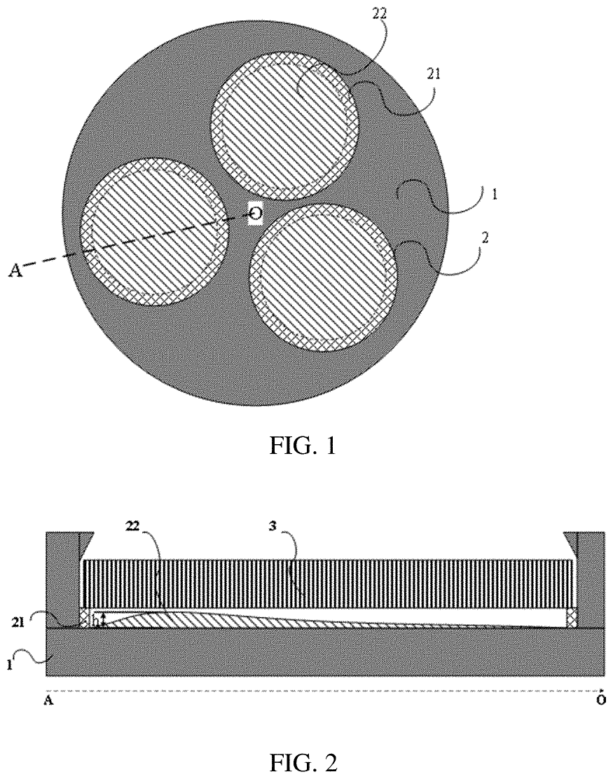

FIG. 1 shows a top view of a wafer susceptor 1. Point O is a circle center of the wafer susceptor 1. In the embodiment, three grooves 2 are disposed on the wafer susceptor for placing wafer 3. In other embodiments, the number of grooves 2 on the wafer susceptor may be set according to the size of the wafer, and the present application does not limit the number of grooves 2 on the wafer susceptor 1.

FIGS. 2-7 are cross-sectional structure diagrams of one groove in the wafer susceptor 1. A step structure 21 may be disposed on an edge of the groove 2, and the step structure 21 is configured to place the wafer 3, so that there is a distance between the wafer 3 and the bottom of the groove 2, and there is radiant heat conduction between the wafer 3 and the groove 2 rather than contact heat conduction, which promotes uniformity of surface temperature of the wafer 3. The convex structure 22 is disposed at the bottom of the groove 2, the convex structure 22 is asymmetrical, and a convex part of the convex structure 22 is not located in a circle center of the wafer 3, but far away from a circle center O of the entire wafer susceptor 1.

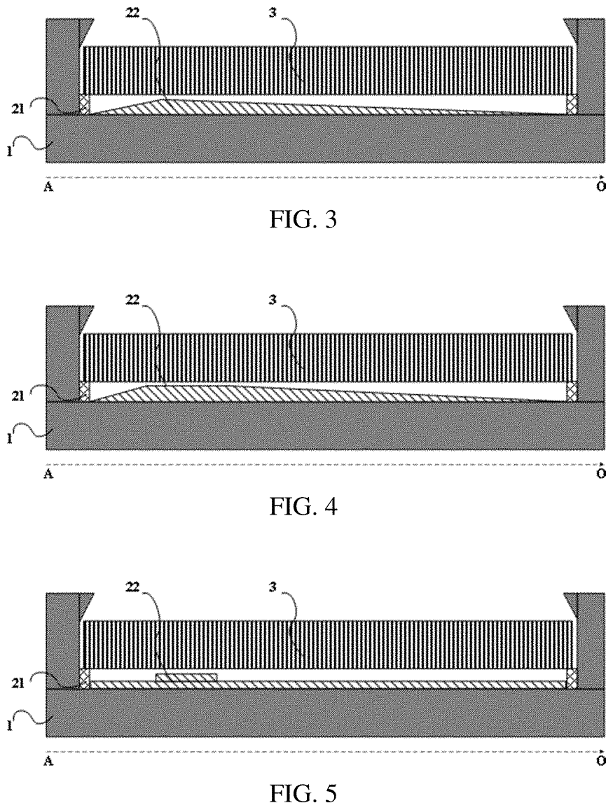

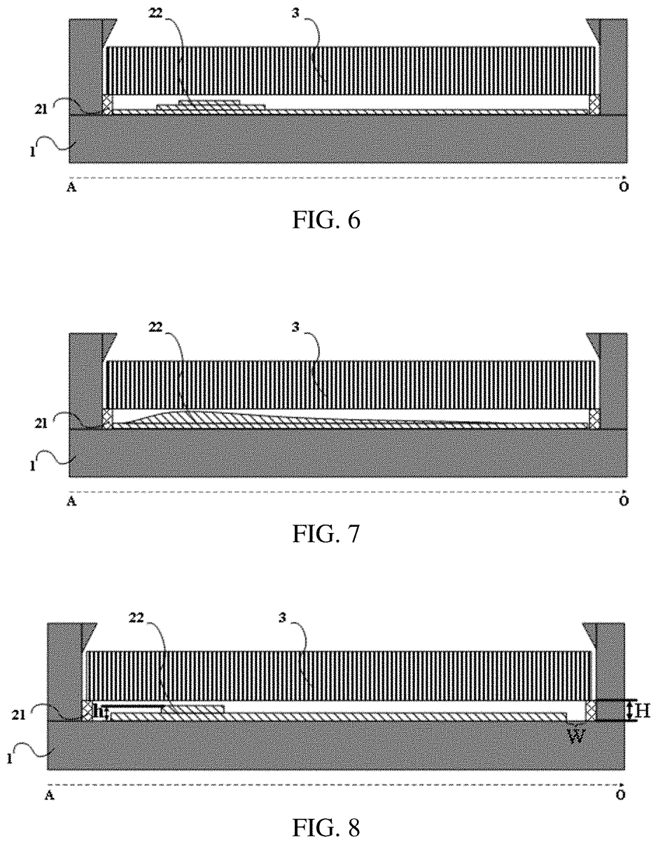

Further, a cross-sectional shape of the convex structure 22 includes one or a combination of more of arc, triangle, trapezoid and rectangle. The convex structure includes a single-layer structure or a multi-layer structure. Specifically, the shape of the convex structure 22 is arc as shown in FIG. 2; the shape of the convex structure 22 may be triangular as shown in FIG. 3; and the shape of the convex structure 22 may be trapezoidal as shown in FIG. 4. Further, the shape of the convex structure 22 may include rectangle, and the shape of the convex structure 22 may include a double-layer rectangle as shown in FIG. 5, or the shape of the convex structure 22 may include three-layer rectangle as shown in FIG. 6. It should be understood that the shape of the convex structure 22 may also include other layers, which is not limited here.

In other embodiments, the shape of the convex structure 22 may include a combination of arc and rectangle as shown in FIG. 7, and the shape of the convex structure 22 may also be a combination of other shapes. It should be understood that as long as it is ensured that the entire convex structure is asymmetrical, the convex part of the convex structure is far away from the circle center O of the wafer susceptor 1, so that when the wafer 3 becomes convex, the heating temperature of a convex part of the wafer 3 is increased by the convex part of the convex structure 22.

To avoid repetition, FIGS. 3-7 show cross-sectional structure diagrams of a groove taken along AO.

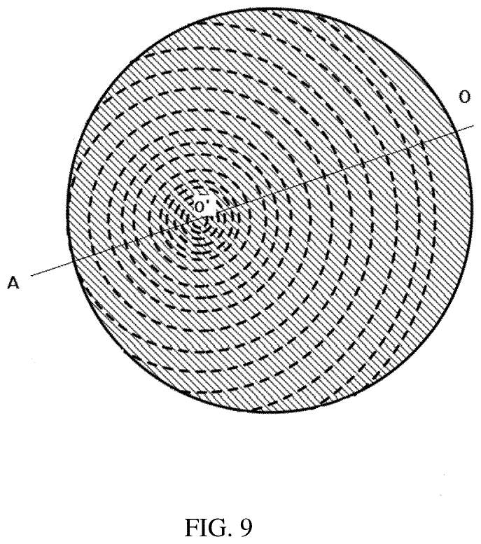

In the present application, the convex structure 22 is asymmetrical. From the AO cross section, the convex part of the entire arc structure is far away from the circle center O of the entire wafer susceptor 1. The above FIGS show cross-sectional shapes of the convex structure. For the convenience of understanding the present application, FIG. 9 shows a top view of the convex structure, which is illustrated by a contour map, and position O′ is the highest point of the convex structure 22. In FIG. 9, with O′ as a center, the height of the convex structure 22 is getting smaller and smaller towards an edge of the groove. It should be understood that the contour map of the convex structure is provided in the present application for the purpose of understanding the three-dimensional shape of the convex structure 22 in the present application by those skilled in the art, without limiting the specific change of the high h of the convex structure 22. The contour line shown in the top view of the convex structure may also be elliptical, and the top view of the convex structure is not limited by the present application as long as the convex part of the convex structure is far away from the circle center of the wafer susceptor 1.

Further, as shown in FIG. 8, there may be a distance W between the convex structure 22 and the step structure 21 in a horizontal direction, and the size of the distance W may be set according to the optimal solution of the temperature distribution of the preparation environment.

In the embodiment, as shown in FIG. 8, there is a distance between the convex structure 22 and the wafer 3, namely, the height h of the convex structure 22 is not greater than the height H of the step structure 21 in the groove, and uneven heating of the wafer 3 resulted by contact heat conduction between the convex structure 22 and the wafer 3 is avoided.

Further, the height h of the convex structure 22 is in a range of 50 μm-150 μm, and the height H of the step structure 21 is in a range of 100 μm-300 μm.

Through the improvement of the present application, when the substrate is placed on the step structure of the wafer susceptor and the entire wafer susceptor is placed in a reaction chamber, airflow in the reaction chamber blows towards the periphery through the circle center of the wafer susceptor, thereby forming other epitaxial layers on the substrate. The farther away from the circle center of the wafer susceptor, the higher MO source distribution, and the substrate bulges in the position away from the circle center of the wafer susceptor, the temperature of a convex position is lower than that of other positions on the substrate, and the wavelength of the epitaxial wafer is larger. Therefore, an asymmetrical convex structure is disposed at the bottom of the groove where the epitaxial substrate is placed, and the convex part of the convex structure is far away from the circle center of the wafer susceptor, so that the surface temperature of a portion of the substrate far away from the circle center of the wafer susceptor is increased. That is, the temperature of the convex position is basically the same as that of other positions on the substrate, the surface of the entire substrate is heated more uniformly, and thus the wavelength of the epitaxial wafer formed on the substrate is also more uniform, and the quality of the epitaxial wafer is promoted.

It should also be noted that, in the description of the present application, unless otherwise stated and defined, the terms “setup”, “mounted”, “coupled”, and “connected” should be understood in a broad sense. For example, the meaning of the terms may be a fixed connection, a detachable connection, or an integral connection; the meaning of the terms may be a mechanical connection or an electrical connection; and the meaning of the terms may be a direct connection, or an indirect connected through an intermediate medium, or the meaning of the terms may be an internal communication of two components. For those of ordinary skill in the art, the specific meanings of the above terms in the present application may be understood depending on specific circumstances.

It should be noted that similar reference numerals and letters indicate similar items in the following accompanying drawings, so once an item is defined in one accompanying drawing, it need not be further defined and explained in the subsequent accompanying drawings.

In the description of the present application, it should be noted that the orientation or position relations indicated by the terms “center”, “above”, “below”, “left”, “right”, “vertical”, “horizontal”, “inside”, “outside”, etc. are based on the orientation or position relations shown in the accompanying drawings, or are the orientation or position relations in which the product of the present application is usually placed in use, merely for facilitating the description of the present application and simplifying the description, but not intended to indicate or imply that the referred device or element must be in a particular orientation, or constructed and operated in a specific orientation, and therefore they should not be construed as a limitation on the present application. In addition, the terms “first”, “second”, “third”, etc. are only used to distinguish descriptions and should not be interpreted as indicating or implying relative importance.

The above descriptions are merely preferred embodiments of the present application and are not intended to limit the present application. For those skilled in the art, the present application may have various modifications and changes. Any modification, equivalent replacement, and improvement made within the spirit and principle of the present application shall be included in the protection scope of the present application.

What is claimed is:

1. A wafer susceptor, comprising:
a plurality of grooves; and
a convex structure disposed in one groove of the plurality of grooves, wherein the convex structures is asymmetrical, and a convex part of the convex structure is far away from a circle center of a wafer susceptor.

2. The wafer susceptor according to claim 1, wherein a cross-sectional shape of the convex structure comprises one of arc, triangle, trapezoid and rectangle.

3. The wafer susceptor according to claim 1, wherein a cross-sectional shape of the convex structure comprises a combination of more of arc, triangle, trapezoid and rectangle.

4. The wafer susceptor according to claim 1, wherein the convex structure comprises a single-layer structure.

5. The wafer susceptor according to claim 1, wherein the convex structure comprises a multi-layer structure.

6. The wafer susceptor according to claim 1, wherein a height of the convex structure is in a range of 50 μm-150 μm.

7. The wafer susceptor according to claim 1, wherein the wafer susceptor further comprises a step structure disposed on an edge of the groove.

8. The wafer susceptor according to claim 7, wherein there is a distance between the convex structure and the step structure in a horizontal direction.

9. The wafer susceptor according to claim 7, wherein a height of the step structure is in a range of 100 μm-300 μm.

10. The wafer susceptor according to claim 7, wherein a height of the convex structure is not greater than a height of the step structure.

11. The wafer susceptor according to claim 1, wherein from the highest point of the convex part towards an edge of the groove, a height of the convex structure becomes smaller and smaller.

12. The wafer susceptor according to claim 11, wherein the highest point of the convex part is disposed, with respect to a center of the groove, far away from the circle center of the wafer susceptor.
